(19) United States
(12) Patent Application Publication
(10) Pub. No.: US 2017/0100975 A1
(43) Pub. Date: Apr. 13, 2017

(54) Automatic Trailer Lighting Control

(71) Applicant: Ford Global Technologies, LLC, Dearborn, MI (US)

(72) Inventor: J. Elias Ruiz, De Mexico (MX)

(21) Appl. No.: 14/881,260

(22) Filed: Oct. 13, 2015

(51) Int. Cl. B60D 1/64; G01R 31/02; G01R 31/00

(52) U.S. Cl. CPC B60D 1/64; G01R 31/006; G01R 31/026

(57) ABSTRACT

A vehicle includes a magnetic switch and a controller. The magnetic switch is coupled with a trailer connection receptacle housing and aligned with a magnet in a cap of the housing while closed. The controller is configured to, in response to detecting an open position of the cap based on a state of the magnetic switch, periodically supply a voltage pulse less than an operating voltage across contacts of the housing to detect continuity therebetween. The controller is further configured to, in response to detecting a closed position of the cap, inhibit the voltage pulse. The magnetic switch may be a reed switch.

### TECHNICAL FIELD

This disclosure relates to operation and structure of a trailer plug receptacle for a vehicle that includes a switch mechanism to detect a position of a receptacle cover.

### BACKGROUND

Lighting systems for vehicles include exterior lights, interior lights, a light switch, a connector to illuminate a trailer or secondary lights such as snow plow lights, and a controller. Exterior lights include headlights, tail lights, and running lights, and interior lights include dome lights, ambient lights, and door lights. A light switch typically provides a signal to a controller such as a Body Control Module (BCM). The light switch may include a headlight switch, a brake light switch, or a reverse gear selection switch. The BCM may include drivers such as intelligent metal oxide semiconductor field effect transistors (MOSFETs) to supply power to the lights. Upon power being supplied to the lights, the lights will illuminate at a specific color determined by vehicle designers based on the location and function of the lights. Vehicles that tow trailers use a trailer plug receptacle configured to accept a trailer plug and conduct a current to the trailer. The trailer plug is designed to provide power to lights and components of the trailer in unison with the vehicle lighting and vehicle operations. The trailer plug is often connected in parallel with the rear lights of the vehicle.

### SUMMARY

A vehicle includes a magnetic switch and a controller. The magnetic switch is coupled with a trailer connection receptacle housing and aligned with a magnet in a cap of the housing while closed. The controller is configured to, in response to detecting an open position of the cap based on a state of the magnetic switch, periodically supply a voltage pulse less than an operating voltage across contacts of the housing to detect continuity therebetween.

A vehicle trailer connection system includes a magnetic switch and a controller. The magnetic switch is coupled with a trailer connector receptacle housing and aligned with a magnet in a cap of the housing while closed. The controller is configured to periodically modulate a voltage between contacts of the housing based on a state of the switch indicative of an open position of the cap, and activate the receptacle based on a resistance between the contacts being within a predetermined range.

A trailer connection system for a vehicle includes a housing, a plurality of magnetic switches, and a plurality of caps. The housing includes a plurality of connector receptacles. The plurality of magnetic switches is proximate with and corresponds to the plurality of connector receptacles, and is coupled with the housing. The plurality of caps corresponds to the connector receptacles, and each of the caps is pivotally coupled with the housing and includes a magnet proximate to one of the magnetic switches when closed.

### BRIEF DESCRIPTION OF THE DRAWINGS

FIG. 1A is a left/front perspective view of a vehicle including exterior lights.

FIG. 1B is a left/rear perspective view of the vehicle shown in FIG. 1 including exterior lights and a trailer plug receptacle.

FIG. 2A is an exemplary trailer plug receptacle.

FIG. 2B is an exemplary trailer plug receptacle including a magnetic switch with a 4-way plug cover in an open position.

FIG. 2C is an exemplary trailer plug receptacle including a magnetic switch with a 7-way plug cover in an open position.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The embodiments of the present disclosure generally provide for a plurality of circuits or other electrical devices. All references to the circuits and other electrical devices and the functionality provided by each, are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that the term lamp and light bulb may be implemented using an incandescent light bulb, a halogen light, a Light Emitting Diode (LED), a compact fluorescent light (CFL) bulb, a High-intensity discharge lamps (HID lamps), or any light source acceptable for use as a lamp on vehicle by the World Forum for Harmonization of Vehicle Regulations (ECE Regulations) or the Federal Motor Vehicle Safety Standards (FMVSS). It is also recognized that the term filament may be implemented using an illumination structure for the corresponding lamp. For example, a P-N junction in an LED corresponds to a filament in an incandescent bulb. It is further recognized that any circuit or other electrical device disclosed herein may include any number of microprocessors, integrated circuits, memory devices (e.g., FLASH, random access memory (RAM), read only memory (ROM), electrically programmable read only memory (EPROM), electrically erasable programmable read only memory (EEPROM), or other suitable variants thereof) and software which co-act with one another to perform operation(s) disclosed herein. In addition, any one or more of the electric devices may be configured to execute a computer-program that is embodied in a non-transitory computer readable medium that is programmed to perform any number of the functions as disclosed.

Many vehicles such as trucks, sport utility vehicles, cross-over vehicles and some passenger vehicles are designed to tow trailers. The vehicles typically include a connector at the rear of the vehicle near a trailer hitch or hitch receiver. The trailer hitch is a structure in which a trailer is coupled to a vehicle. The connector provides the electrical connection for the vehicle-trailer interaction such as providing power to running lights, stop lights, turn lights, backup lights and electric brakes. Typically, a trailer connector also referred to as a trailer plug includes electrical connections in parallel with the rear lights of the vehicle and may include a connection to connect electric brakes of the trailer to a brake controller in the vehicle. A Trailer Tow Lighting Module (TTLM) has recently been introduced to provide smart features for trailers including lamp outage detection, a trailer status feedback to a driver of the vehicle, a perimeter alarm and a battery charge control. This new module represents a significant improvement to the trailer lighting technology. However, the performance of the connector and module is vulnerable to exterior factors including environment and weather such as snow, ice, rain, salt spray, dirt, and mud. To increase reliability and operational performance, the TTLM uses a polling strategy to detect the presence of a trailer, this method determinates if a load is attached to the vehicle. If a load is attached to the vehicle and detected by the impedance between the contacts, the module may provide feedback by signaling other module such as outputting a signal to a driver information console (DIC) or instrument cluster indicative of the message “Trailer Connected”. If the loads are not connected as possibly determined by a high impedance between the contacts, the TTLM may provide a signal indicative of the message “Trailer Disconnected”. Weather factors such as ice, snow, dirt, or mud accumulated inside the trailer tow connector may provide an electrical connection between the contacts with an impedance in an acceptable range for a connected trailer. These weather factors may be received by the TTLM as a false positive reading as the salinity of water could provide a resistive path that may be interpreted as an electrical trailer load. Also, certain types of dust, pollution, dirt water, mud, or ice may provide a resistive path that may be interpreted as an electrical trailer load.

A smart trailer tow connector may include a 4 way connector, a 7 way connector, or a combination of a 4 way and 7 way connector. A physical difference between the two connectors is that the smart trailer tow connector adds a cap, also referred to as a lid or gate, detection system that detects if the cap is in an open position or a closed position. The detection system is based on two switches that provide a signal to the TTLM. The signal may be configured as an active high signal or an active low signal. For example, a controller may use a general purpose input/output (GPIO) pin configured as an input having a pull-up resistor between the GPIO pin and module power such as Vcc or Vdd supplied to the module. The module power may be 9V, 5V, 3.3V or some voltage level less than 12V, which is used to power the circuitry of the module. This is different from the battery voltage that is typically 12.6V when fully charged and 12.1V when discharged, however, during operation, the voltage may drop lower than the 12.1 V due to a voltage drop associated with current flow and resistance of wire and electronics. Here the switch, when closed, pulls the GPIO pin down indicating that the switch is closed. Alternatively, the GPIO may be connected to a pull-down resistor connected to chassis ground wherein a switch coupled to module power such as Vcc, when closed, pulls the GPIO pin up to module power to indicate that the switch is closed. A switch, such as a reed switch, may be embedded into the connector and aligned with a magnet in the cap such that the reed switch changes state when moved from open to close in response to movement of the cap of the connector. A reed switch is a pair of contacts on ferrous metal reeds in a hermetically sealed glass envelope. When the reed switch is in the presence of a magnetic field greater than a predetermined threshold such as resulting from being proximate to a magnet, the state of the switch changes state from when no magnetic field is present. A normally closed switch opens in the presence of a magnetic field and a normally open switch closes in the presence of a magnetic field. Also, the switch may be a single pole or a double pole switch. A single pole switch may be coupled with the TTLM, while a double pole switch may have one pole coupled with the TTLM and the other pole coupled in series with power to the connector.

In one embodiment, when the cap of the connector housing is closed, the magnetic switch will provide a signal to the ECU indicating that the cap is closed. When the cap is closed and a plug is not inserted into the housing, the contacts may have resistive paths due to rain, ice, snow, moisture, dirt, salt spray, or other debris. When the cap is closed, the controller may inhibit the application of power to the contacts thus avoiding any possible resistive path between the contacts and the associated leakage currents. When the door is open, the switch will change state that is detected by the controller. Based on detection that the cap is open, the controller may periodically apply a low voltage to the contacts to detect if a load is engaged, the low voltage includes 5V or 3.3V and is a voltage less than a battery voltage being approximately 12V. The low voltage is applied to detect a connected trailer and to distinguish between a trailer and a resistive path such as rain, ice, snow, moisture, dirt, salt spray, or other debris. As the cap of the housing is opened prior to inserting and connection with the plug of a trailer, the TTLM algorithm may be configured to start a time counter that will allow to the system to define if it is a real connection condition. The timer may wake up periodically to apply a voltage pulse at a voltage less than the battery voltage onto the contacts. Based on the voltage pulse, the controller may determine an impedance between the contacts of the connector. When the impedance between the contacts of the connector is within a range of impedances, the controller may generate a signal to route signals to the connector.

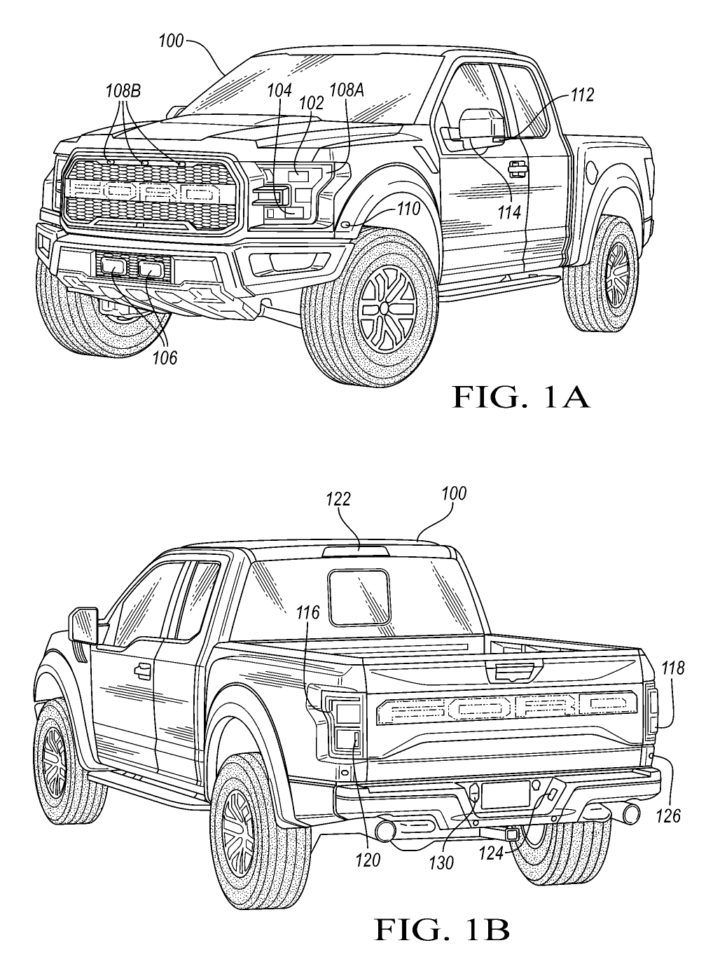

FIG. 1A is a right/front perspective view of a vehicle 100 including exterior lights. Lighting of a motor vehicle is regulated by the Federal Motor Vehicle Safety Standard 108 (FMVSS 108) administered by the United States Department of Transportation's (DOT) National Highway Traffic Safety Administration (NHTSA). Exterior lights include a headlight 102 that may have a high-beam setting and a low-beam setting. The low-beam setting typically limits an intensity and height of the light beam from the headlight, while the high-beam setting typically has an illumination pattern greater than the illumination pattern of the low beam setting. Another exterior light is a front turn signal 104. Vehicles typically have a left front turn signal and a right front turn signal. Some vehicles have fog lights 106 also referred to as driving lights. Vehicle 100 also includes front running lights 108; however, some vehicles may utilize turn signals in place of running lights 108 by using a single multi-filament bulb or multiple single filament bulbs in the front turn signals. Front cornering lights 110 are usually illuminated while the running lights 108 are illuminated. A minor light 112 may be illuminated along with the running lights 108. The mirror light 112 may have a single bulb having a dual filament arrangement or may have multiple single filament bulbs such that an intensity of the mirror light 112 flashes when the turn signals are activated. In some implementations, a vehicle may also have a quarter panel light located between the front wheels well and the hinge plane of the front door. The quarter panel light may be illuminated along with the running lights 108 and similar to the minor light 112 may have a dual filament arrangement such that the intensity increases and decreases when the turn signals are activated. The vehicle 100 may also have a puddle light 114 that is typically white and configured to illuminate an area of the ground to the side of the vehicle 100. The puddle lamps 114 may be activated when the vehicle is stationary to illuminate a side of the vehicle 100 such as when the vehicle is parked and people are entering the vehicle 100 and exiting the vehicle 100.

FIG. 1B is a left/rear perspective view of the vehicle 100 shown in FIG. 1 including exterior lights. The rear of the vehicle 100 has tail lights 116 also referred to as rear lights or back lights, such as a right and a left tail light that may be light together indicative of application of a brake of the vehicle, flashing together indicative of a hazard signal, or flashing independently indicative of activation of a turn signal. In some implementations, the tail lights 116 may be activated at a given intensity, i.e. a low intensity, with activation of running lights, and activate at an increased intensity, i.e. high intensity, according to activation of brakes, turn signals, or hazard switch. A back-up light 118 is typically activated when a transmission mode to reverse the vehicle is selected. The back-up light is typically white and is designed to illuminate an area proximate to the rear of the vehicle 100. The back-up lights are typically brighter than other rear facing lights, and may be activated when the vehicle 100 is stationary or parked to illuminate the area proximate to the rear of the vehicle 100. The vehicle may have dedicated rear running light 120; however, some vehicles may utilize the rear turn signals in place of rear running lights 120 by using a single multi-filament bulb or multiple single filament bulbs in the rear turn signal. A rear license plate light 124 usually illuminates an area around the license plate with a white light. Rear cornering lights 126 are usually illuminated while the running lights 120 are illuminated. Also, the vehicle 100 may include a center high mount stop light (CHMSL) 122. When the vehicle 100 is pulling a trailer, many of the lights may be partially or completely blocked by the trailer. A trailer plug connector 130, also referred to as a trailer plug receptacle, may be disposed on the rear of the vehicle 100 near a trailer hitch. The trailer plug connector 130 provides an electrical connection from the vehicle 100 to the trailer. The connector 130 may be electrically connected in parallel with the rear tail lights or may be electrically connected to a controller such as a TTLM or may be electrically connected to controller or processor in a BCM.

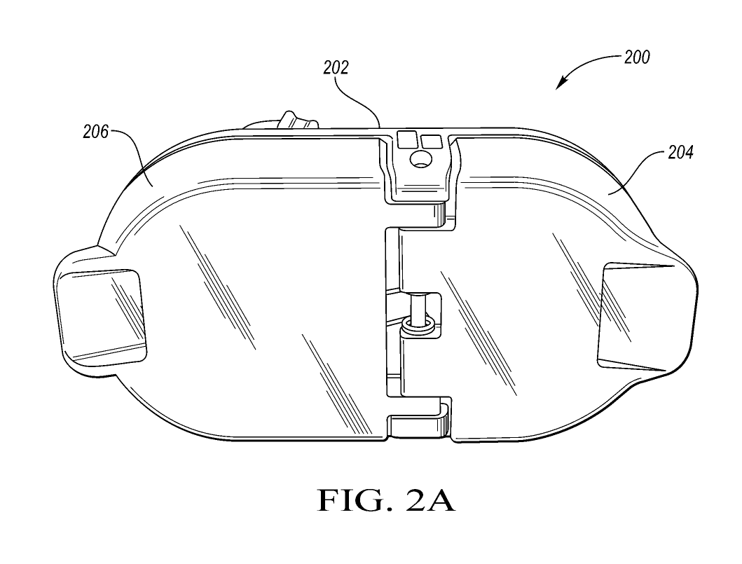

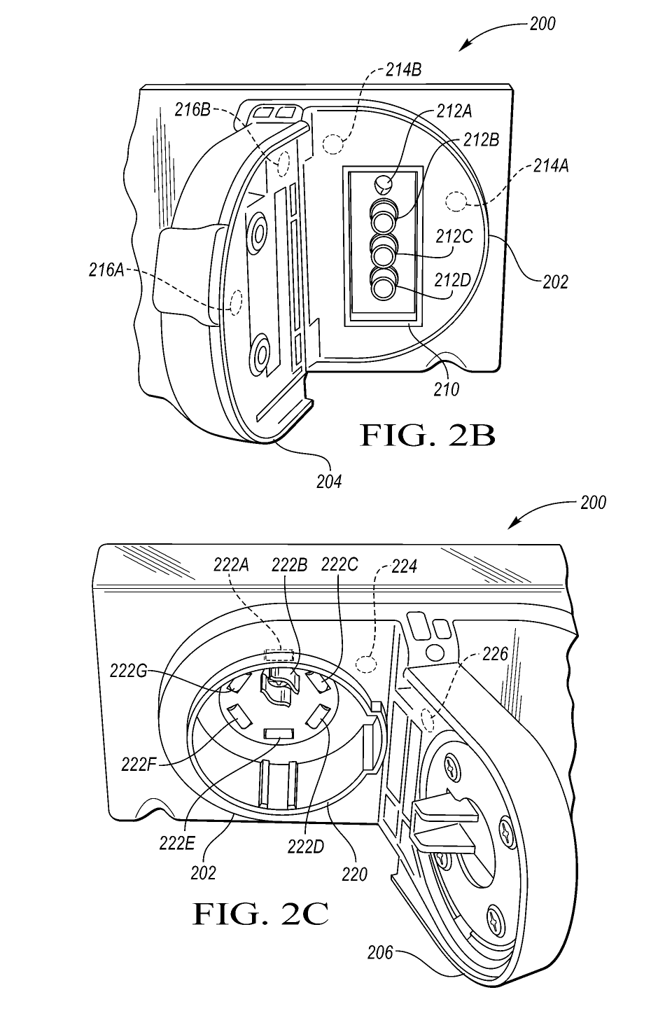

FIG. 2A is an exemplary trailer plug receptacle 200. The trailer plug receptacle 200 also referred to as a trailer connection receptacle includes a receptacle housing 202, a 4-way cap 204 for the 4-way connector receptacle connector, and a 7-way cap 206 for the 7-way connector receptacle connector. The trailer plug receptacle 200 is shown as a combination 4-way and 7-way receptacle; however, a trailer plug receptacle may include a single plug receptacle, such as a flat 4-way trailer plug receptacle or a round 7-way blade trailer plug receptacle. The trailer plug receptacle may be constructed of a metal, an alloy, a plastic, or other suitable material. The use of plastic may include a polymer such as polyamide or polypropylene or a polymer blend such as polyethylene/acrylonitrile butadiene styrene or polycarbonate/acrylonitrile butadiene styrene. A housing made of plastic may be constructed by injection molding such that a magnet or magnetic switch may be embedded within the housing.

FIG. 2B is an exemplary trailer plug receptacle 200 including a magnetic switch 214 with a 4-way plug cap 204 in an open position. The trailer plug receptacle 200 includes a receptacle housing 202 and a 4-way cap 204 for the 4-way receptacle connector 210. In the receptacle connector 210, are contacts 212 that are electrically isolated and secured in place by the housing 202. A magnetic switch 214 may be located at multiple places along the face of the housing 202. This illustration shows a first position for a first magnetic switch 214A and second position for a second magnetic switch 214B. When the cap 204 is closed, the first magnetic switch 214A is aligned with a first magnet 216A. Alternatively, when the cap 204 is closed, the second magnetic switch 214B is aligned with a second magnet 216B. In another embodiment, a magnetic switch may be embedded in the housing beneath the hinge and the magnetic may be coupled with the hinge of the cap 204 such that when the cap 204 is closed, the magnetic switch is aligned with the magnet to change the state of the magnetic switch, and when the cap 204 is open, the magnetic switch returned to a rest or normal state.

A controller such as the TTLM may be coupled with the magnetic switch 214, and upon detection that the switch 214 is in a state indicative of the cap 204 being in an open position, the controller may cause a voltage to be applied to a contact 212.

A typical configuration of the contacts 212 for a 4-way flat trailer connector as shown in FIG. 2B is as follows.

Contact 212A is a ground connection to a chassis of the trailer. The contact 212A typically uses a 16 American Wire Gauge (AWG) conductor. When measuring conductivity, resistance, or an impedance of a load on the trailer, the measurement is typically measured using contact 212A as a reference.

Contact 212B is a coupled to tail lamps, clearance lamps, outline marker lamps, running lights, and a license/registration plate lamp. The contact 212B typically uses an 18 AWG conductor. Conductivity, resistance, or impedance of a trailer load associated with contact 212B is typically measured between contact 212B and contact 212A.

Contact 212C is coupled with a left turn signal, stop lamp. The contact 212C typically uses an 18 AWG conductor. Conductivity, resistance, or impedance of a trailer load associated with contact 212B is typically measured between contact 212C and contact 212A.

Contact 212D is coupled with a right turn signal, stop lamp. The contact 212D typically uses an 18 AWG conductor. Conductivity, resistance, or impedance of a trailer load associated with contact 212B is typically measured between contact 212D and contact 212A.

When detecting conductivity, resistance, or impedance, measurements may be made between the ground contact 212A and another contact 212B-D, or measurements may be made between two signal contacts such as between 212B and 212C or 212B and 212D. Although the most common failure mode is a resistive path to ground (i.e., resistive path between contact 212A and another signal), wires after prolonged contact and rubbing may also form a resistive path. The controller may be used to check if there are any resistive paths between contacts 212 by applying a voltage across multiple contact pairs. For example, between 212B and 212C, 212B and 212D, and between 212C and 212D. The voltage applied may be less than the battery voltage as the lower voltage will not stress the insulating material. In another embodiment, the voltage applied is the battery voltage as that is the voltage applied during operation, it can be used to detect a resistive path during operation. Also, in further embodiment, the voltage may be greater than the battery voltage. The advantage of using a voltage greater than the battery voltage is that at an increased voltage the breakdown of the insulating material due to possible arcing maybe determined. Also, a combination of multiple voltage levels may be used in progression to test the wiring harness of the trailer.

FIG. 2C is an exemplary trailer plug receptacle 200 including a magnetic switch 2224 with a 7-way plug cap 206 in an open position. The trailer plug receptacle 200 includes a receptacle housing 202 and a 7-way cap 206 for the 7-way receptacle connector 220. In the receptacle connector 220, are contacts 222 that are electrically isolated and secured in place by the housing 202. A magnetic switch 224 may be located at multiple places along the face of the housing 202. This illustration shows an exemplary position for a magnetic switch 224. When the cap 206 is closed, the magnetic switch 224 is aligned with a magnet 226. In another embodiment, a magnetic switch may be embedded in the housing beneath the hinge and the magnetic may be coupled with the hinge of the cap 206 such that when the cap 206 is closed, the magnetic switch is aligned with the magnet to change the state of the magnetic switch, and when the cap 206 is open, the magnetic switch returned to a rest or normal state.

A typical configuration of the contacts 222 for a 7-way round trailer connector as shown in FIG. 2B is as follows.

Contact 222G is a ground connection to a chassis of a trailer. The contact 222G typically uses a 12 AWG conductor. When measuring conductivity, resistance, or an impedance of a load on the trailer, the measurement is typically measured using contact 222G as a reference.

Contact 222A is coupled with a left turn signal, stop lamp. The contact 222A typically uses a 16 AWG conductor. The contact 222A typically uses a 16 AWG conductor. Conductivity, resistance, or impedance of a trailer load associated with contact 222A is typically measured between contact 222A and contact 222G.

Contact 222C—Tail lamps, clearance lamps/outline marker lamps and registration plate lamp. The contact 222C typically uses a 16 AWG conductor. Conductivity, resistance, or impedance of a trailer load associated with contact 222C is typically measured between contact 222C and contact 222G.

Contact 222D is coupled with auxiliary +12V power that is typically enabled when the vehicle ignition is on. The contact 222D typically uses a 12 AWG conductor. Conductivity, resistance, or impedance of a trailer load associated with contact 222D is typically measured between contact 222D and contact 222G.

Contact 222E is coupled with a right turn signal, stop lamp. The contact 222E typically uses a 16 AWG conductor. Conductivity, resistance, or impedance of a trailer load associated with contact 222E is typically measured between contact 222E and contact 222G.

Contact 222F is coupled with an electric brake control. The contact 222F typically uses a 12 AWG conductor. Conductivity, resistance, or impedance of a trailer load associated with contact 222F is typically measured between contact 222F and contact 222G.

Contact 222B is coupled with at least one reversing lamp and may include a control signal to block a surge to the trailer brakes when reversing. The contact 222B typically uses a 16 AWG conductor. Conductivity, resistance, or impedance of a trailer load associated with contact 222B is typically measured between contact 222B and contact 222G.

When detecting conductivity, resistance, or impedance, measurements may be made between the ground contact 222G and another contact 222A-F, or measurements may be made between two signal contacts such as between 222D and 222C or 222B and 222F. Although the most common failure mode is a resistive path to ground (i.e., resistive path between contact 222G and another signal), wires after prolonged contact and rubbing may also form a resistive path. The controller may be used to check if there are any resistive paths between contacts 222 by applying a voltage across multiple contact pairs. For example, between 222B and 222C, 222B and 222D, 222B and 222E, 222B and 222F, 222C and 222D, etc. The voltage applied may be less than the battery voltage as the lower voltage will not stress the insulating material. In another embodiment, the voltage applied is the battery voltage as that is the voltage applied during operation, it can be used to detect a resistive path during operation. Also, in further embodiment, the voltage may be greater than the battery voltage. The advantage of using a voltage greater than the battery voltage is that at an increased voltage the breakdown of the insulating material due to possible arcing maybe determined. Also, a combination of multiple voltage levels may be used in progression to test the wiring harness of the trailer.

The operating voltage of the trailer is approximately the battery voltage, in that the operating voltage is lower than the battery voltage by the voltage drop of the resistance of the switch that gates the voltage to the trailer and the voltage drop across the wiring harness to the trailer. Typically, both the voltage drop across the switch and the voltage drop across the wiring harness are less than 2 volts. When detecting continuity, resistance or impedance, the controller may compare the determined characteristic with a low threshold and a high threshold. The thresholds may be based on the gauge wire allowed for the trailer. For example, a contact to an 18 gauge wire may have a lower resistance threshold of 3 ohms. If the controller for the contact to the 18 AWG limits by design the current to 3.5 amps, applying Ohm's law provides a minimum resistance of V/I being 12V/3.5 amps or 3.4 ohms. Likewise, for a 16 AWG may have a lower resistance threshold of 2.4 ohms. Here the controller may consider that 16 AWG can carry more current and limit the current to 5 amps resulting in 12/5 or 2.4 ohms. And for 12 AWG, the lower resistance threshold may be 1 ohm.

In an alternative embodiment, a receptacle housing other trailer plug configurations may include a magnetic switch in the receptacle housing and a magnetic cap. The other trailer plug configurations include ISO 1185/SAE J560 along with other 4 way, 5 way, 6 way and 7 way configurations.

Control of the lights in many modern vehicles is performed by controller or module such as a Body Control Module (BCM). The processes, methods, or algorithms disclosed herein may be deliverable to or implemented by a processing device, controller, or computer, which may include any existing programmable electronic control unit or dedicated electronic control unit. Similarly, the processes, methods, or algorithms may be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms may also be implemented in a software executable object. Alternatively, the processes, methods, or algorithms may be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

What is claimed is:

1. A vehicle comprising:
a magnetic switch coupled with a trailer connection receptacle housing and aligned with a magnet in a cap of the housing while closed; and
a controller configured to, in response to detecting an open position of the cap based on a state of the magnetic switch, periodically supply a voltage pulse less than an operating voltage across contacts of the housing to detect continuity therebetween.

2. The vehicle of claim 1, wherein the controller is further configured to, in response to detecting a closed position of the cap, inhibit the voltage pulse.

3. The vehicle of claim 1, wherein the magnetic switch includes a pair of contacts on ferrous metal reeds in a hermetically sealed glass envelope.

4. The vehicle of claim 1, wherein the controller is configured to detect continuity based on resistance between the contacts being greater than a low resistance threshold and less than a high resistance threshold.

5. The vehicle of claim 1, wherein the period between consecutive pulses is greater than 10 seconds.

6. The vehicle of claim 5, wherein a duration of each voltage pulse is less than 1 second.

7. The vehicle of claim 6, wherein the controller is further configured to, in response to detecting an open position of the cap based on a state of the magnetic switch, periodically supply a voltage pulse at an operating voltage of the vehicle.

8. The vehicle of claim 1, wherein the magnet is located in a hinge of the cap such that the cap in a closed position is aligned with the magnetic switch, and the magnetic switch is located in the housing along the hinge.

9. A vehicle trailer connection system comprising:
a magnetic switch coupled with a trailer connector receptacle housing and aligned with a magnet in a cap of the housing while closed; and
a controller configured to periodically modulate a voltage between contacts of the housing based on a state of the switch indicative of an open position of the cap, and activate the receptacle based on a resistance between the contacts being within a predetermined range.

10. The system of claim 9, wherein the voltage is less than a trailer operating voltage.

11. The system of claim 9, wherein the voltage is a trailer operating voltage.

12. The system of claim 9, wherein the controller is further configured to, in response to detecting a closed position of the cap, inhibit modulation of the voltage.

13. The system of claim 9, wherein the magnetic switch is a reed switch.

14. The system of claim 9, wherein the period between the modulation of the voltage is greater than 10 seconds.

15. The system of claim 9, wherein the modulation of the voltage includes a duration of a pulse greater than 1 microsecond and less than 1 second.

16. The system of claim 9, wherein the range is greater than 1 ohm and less than 1 megaohm.

17. A trailer connection system for a vehicle comprising:
a housing including a plurality of connector receptacles;
a plurality of magnetic switches proximate with and corresponding to the plurality of connector receptacles and coupled with the housing; and
a plurality of caps corresponding to the connector receptacles, each of the caps being pivotally coupled with the housing and including a magnet proximate to one of the magnetic switches when closed.

18. The system of claim 17 further including a controller configured to, in response to detecting an open position of one of the plurality of caps based on a state of the corresponding magnetic switch, periodically supply a voltage pulse at an operating voltage across contacts of the corresponding connector receptacle to detect continuity therebetween.

19. The system of claim 18, wherein the controller is further configured to, in response to detecting a closed position of each of the plurality of caps, inhibit the voltage pulse.

20. The vehicle of claim 18, wherein the controller is configured to detect continuity based on resistance between the contacts being greater than a low resistance threshold and less than a high resistance threshold.
